(19) United States
(12) Patent Application Publication
(10) Pub. No.: US 2025/0379049 A1
(43) Pub. Date: Dec. 11, 2025

(54) N-TYPE AND P-TYPE SEMICONDUCTOR MATERIAL STACKING TECHNIQUES

(71) Applicant: Abhishek A. Sharma, Portland, OR (US)

(72) Inventor: Abhishek A. Sharma, Portland, OR (US)

(21) Appl. No.: 18/736,798

(22) Filed: Jun. 7, 2024

(51) Int. Cl. H01L 21/02; H01L 21/761

(52) U.S. Cl. CPC H01L 21/02576; H01L 21/02381; H01L 21/02579; H01L 21/761

(57) ABSTRACT

N-type and P-type semiconductor material stacking techniques in accordance with examples described herein may enable the fabrication of IC structures with vertical heterostructures and devices at lower temperatures. In one example, a stack of alternate layers of N-type doped semiconductor material and P-type doped semiconductor material are provided, where at least one layer of the stack is provided by depositing a conductive material including a metal (e.g., via an ALD process) and converting the conductive material into a semiconductor material. In one example, a device may include a first semiconductor region, a second semiconductor region over and in contact with the first semiconductor region, where one of the first and second semiconductor regions includes N-type dopants, and another of the first and second semiconductor regions includes P-type dopants, and a third semiconductor region over and in contact with the second semiconductor region.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of an IC structure including devices fabricated with N-type and P-type semiconductor material stacking techniques, in accordance with various embodiments.

FIGS. 2A and 2B are diagrams of example devices fabricated with N-type and P-type semiconductor material stacking techniques, in accordance with various embodiments.

FIG. 3 is a block diagram of an IC structure with multiple stacked devices, in accordance with various embodiments.

FIG. 4 is a flow diagram of an example method for fabricating an IC structure using N-type and P-type semiconductor stacking techniques, in accordance with some embodiments.

FIGS. 5A-5E provide cross-sectional side views at various stages in the fabrication of an example IC structure according to the method of FIG. 4, in accordance with some embodiments.

FIG. 6 illustrates an example of a vertical transistor fabricated with N-type and P-type semiconductor material stacking techniques, in accordance with various embodiments.

FIG. 7 is a top view of a wafer and dies that may include any of the IC devices disclosed herein, in accordance with any of the embodiments disclosed herein.

FIG. 8 is a side, cross-sectional view of an IC package that may include any of the IC devices disclosed herein, in accordance with various embodiments.

FIG. 9 is a side, cross-sectional view of an IC device assembly that may include any of the IC devices disclosed herein, in accordance with any of the embodiments disclosed herein.

FIG. 10 is a block diagram of an example electrical device that may include any of the IC devices disclosed herein, in accordance with any of the embodiments disclosed herein.

### DETAILED DESCRIPTION

Disclosed herein are integrated circuit (IC) structures including devices fabricated with N-type and P-type semiconductor material stacking techniques, in accordance with various embodiments. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

As mentioned briefly above, the drive for increased device density and functionality within a smaller footprint continues to rise. Vertical or stacked IC structures have the potential to enable further gains in device density. For example, vertical heterostructures (e.g., structures with multiple layers of different semiconductor materials with different properties) may be formed using epitaxial growth techniques; however, the high temperatures (e.g., at or above around 700° C.) conventionally involved in forming such structures may limit their use.

In contrast, N-type and P-type semiconductor material stacking techniques in accordance with examples described herein may enable the fabrication of IC structures with vertical heterostructures and devices at lower temperatures. In one example, a stack of alternate layers of N-type doped semiconductor material and P-type doped semiconductor material are provided, where at least one layer of the stack is provided by depositing a conductive material including a metal (e.g., via an ALD process) and converting the conductive material into a semiconductor material. In one example, converting the conductive material to a semiconductor material may be achieved by exposing the conductive material to a gas at a temperature in a range of about 350 to 600 degrees. In one example, these techniques may be used to form a device (e.g., a vertical transistor or other device) including a stack of alternate layers of N-type doped semiconductor material and P-type doped semiconductor material. For example, a device may include a first semiconductor region, a second semiconductor region over and in contact with the first semiconductor region, where one of the first and second semiconductor regions includes N-type dopants, and another of the first and second semiconductor regions includes P-type dopants, and a third semiconductor region over and in contact with the second semiconductor region, where the third semiconductor region includes a same charge-carrier-type dopant as the first semiconductor region.

IC structures as described herein, in particular IC structures including devices fabricated with N-type and P-type semiconductor material stacking techniques, in accordance with various embodiments, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures including devices fabricated with N-type and P-type semiconductor material stacking techniques, in accordance with various embodiments as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

FIG. 1 is a cross-sectional side view of an IC structure including devices fabricated with N-type and P-type semiconductor material stacking techniques, in accordance with various embodiments.

The IC structure 100 includes front end of line (FEOL) layers 152 and back end of line (BEOL) layers 154. FEOL and BEOL refer to two stages of semiconductor manufacturing. The first stage is referred to as the FEOL. The second stage is referred to as the BEOL. In the FEOL, individual semiconductor devices components (e.g., transistor, capacitors, resistors, etc.) can be patterned in a wafer. In the BEOL, interconnect structures such as conductive lines and conductive vias, separated as needed by an insulator material, can be formed to get the individual components interconnected. The FEOL layer 152 includes a device region 111 over a substrate 102, where the device region 111 includes devices (of which device 103-1 is shown). The substrate 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline.

The device 103-1 is an example of a frontend device (e.g., a frontend transistor such as FinFETs, nanowire transistors, nanoribbon transistors, frontend memory cells, or other frontend devices). The device 103-1 may be considered a “frontend device” due to its location in a FEOL layer. According to examples, the device 103-1 may include a transistor of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Devices in the device region 111 may be electrically isolated from one another by any suitable insulator material 109.

The BEOL layers 154 may include a plurality of backend interconnects electrically coupled to (e.g., in electrically conductive contact with at least portions of) one or more of the plurality of FEOL devices of the FEOL layer 152. Various BEOL interconnect layers 154 may be/include one or more metal layers of a metallization stack of the IC device. Various metal layers of the BEOL interconnect layers 154 may be used to interconnect the various inputs and outputs of the devices (e.g., logic devices) in the FEOL layer 152. In one example, each of the BEOL interconnect layers 154 may include vias and lines/trenches. For example, the BEOL interconnect layer 154-1 includes a via portion 128b and a line or trench/interconnect portion 128a. The trench portion 128a of a metal layer is configured for transferring signals and power along electrically conductive (e.g., metal) lines (also sometimes referred to as “trenches”) extending in the x-y plane (e.g., in the x or y directions), while the via portion 128b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 154 may include only certain patterns of conductive metals, e.g., copper (Cu), aluminum (Al), tungsten (W), or cobalt (Co), or metal alloys, or more generally, patterns of an electrically conductive material, formed in an insulating medium such as an ILD 126. The insulating medium may include any suitable ILD materials such as silicon oxide, carbon-doped silicon oxide, silicon carbide, silicon nitride, aluminum oxide, and/or silicon oxynitride. In some embodiments, the dielectric material 126 disposed between the interconnect structures in different ones of the interconnect layers may have different compositions; in other embodiments, the composition of the dielectric material 126 between different interconnect layers may be the same. The example illustrated in FIG. 1 depicts six interconnect layers 154-1-154-6, however, fewer or more interconnect layers may be present.

The IC structure 100 also includes one or more backend devices (of which the device 103-2 is shown, in a BEOL device region 156). The device 103-2 may be considered a “backend device” due to its location in a BEOL layer. In the example illustrated in FIG. 1, the device 103-2 is shown as being over four interconnect layers (e.g., layers 154-1-154-4); however, backend devices may be present in lower or higher up interconnect layers in the metallization stack. In one example, the device 103-2 may include a transistor of any architecture, such as any non-planar or planar architecture, or other device.

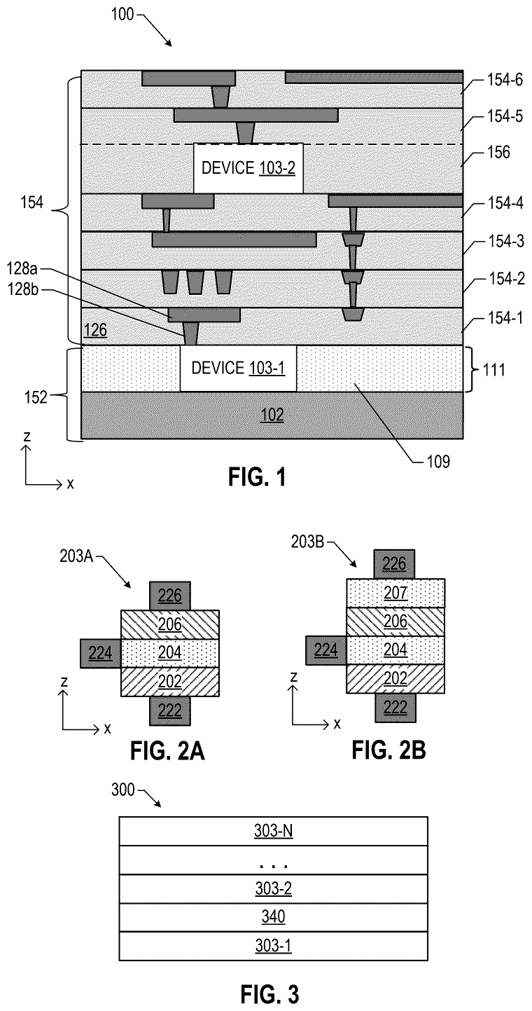

According to examples described herein, the devices 103-1, 103-2 may be fabricated with N-type and P-type semiconductor material stacking techniques, in accordance with various embodiments. FIGS. 2A and 2B illustrate diagrams of example devices fabricated with N-type and P-type semiconductor material stacking techniques, in accordance with various embodiments.

FIG. 2A is a diagram of a vertical transistor 203A fabricated with N-type and P-type semiconductor material stacking techniques. The transistor 203A includes a first semiconductor region 202, a second semiconductor region 204 over and in contact (e.g., directly on or in direct contact) with the first semiconductor region 204, and a third semiconductor region 206 over and in contact with the second semiconductor region 204. The region 202 includes a first semiconductor material, the region 204 includes a second semiconductor material, and the region 204 includes a third semiconductor material. The second semiconductor material of the region 204 is different from (e.g., has a different material composition from) the first and third semiconductor materials of the regions 202, 204. The third semiconductor material may be substantially the same as the first semiconductor material, or may include a different semiconductor material. The transistor 203A may be in FEOL layers (e.g., the device region 111 of FIG. 1) or in BEOL layers (e.g., over one or more interconnect layers 154). For example, the first semiconductor region 202, the second semiconductor region 204, and the third semiconductor region 206 may be in FEOL layers or BEOL layers.

In one example, one of the first and second semiconductor regions 202, 204 includes N-type dopants, and another of the first and second semiconductor regions 202, 204 includes P-type dopants; the third semiconductor region 206 includes a same charge-carrier-type dopant as the first semiconductor region 202, where the charge carrier type of a dopant is either N-type or P-type. N-type dopants are dopants deliberately added to a semiconductor material (e.g., to the emitter and collector regions of an NPN transistor) to introduce additional electrons into the crystal lattice, and that these dopants are also known as “donor” impurities. On the other hand, P-type dopants are dopants deliberately added to a semiconductor material (e.g., to the emitter and collector regions of a PNP transistor) to introduce additional holes into the crystal lattice, and that these dopants are also known as “acceptor” impurities. A semiconductor material with P-type dopants may be referred to as a P-type semiconductor, and a semiconductor material with N-type dopants may be referred to as an N-type semiconductor material.

Thus, the regions 202, 204, 206 are stacked layers of alternate P-type and N-type semiconductor material, where the regions 202 and 206 have the same charge carrier type (e.g., either both the regions 202 and 206 include a P-type semiconductor material or both the regions 202 and 206 include an N-type semiconductor material), and the region 204 has the opposite charge-carrier-type from the regions 202 and 206. For example, if the region 202 includes a P-type semiconductor, the region 204 includes an N-type semiconductor material, and if the region 202 includes an N-type semiconductor, the region 204 includes a P-type semiconductor material. In one example, the transistor 203A is a vertical bipolar junction transistor (BJT), and may be an NPN transistor (in which the regions 202 and 206 include N-type dopants) or a PNP transistor (in which the regions 202 and 206 include P-type dopants). In one such example, the region 204 may be a base region, one of the regions 202 and 206 may be a collector region and another of the regions 202 and 206 may be an emitter region. In other examples, the region 204 may be a channel region, one of the regions 202 and 206 may be a source region, and another of the regions 202 and 206 may be a drain region.

The transistor 203A includes conductive contact structures with the regions 202, 204, 206. Specifically, the transistor 203A includes a first conductive contact structure 222 below and coupled with the first semiconductor material of the region 202, a second conductive contact structure 224 coplanar with and in contact with the second semiconductor material of the region 204, and a third conductive contact structure 226 over and coupled with the third semiconductor material of the region 206. The contact structures 222, 224, 226 include a conductive material (e.g., tungsten or any other suitable conductive material). The contact structures 222, 224, 226 may be coupled with conductive interconnects (e.g., the interconnect portions 128a, 128b of FIG. 1).

According to examples, at least one of the regions 202, 204, 206 includes a semiconductor material that was converted into a semiconductor material from a conductive material including a metal. As a result of its conversion from a metal, a semiconductor material that was converted may have some properties that differ from a semiconductor material that is deposited (e.g., with a chemical vapor deposition (CVD) process, epitaxially grown, etc.). For example, a semiconductor material that was converted from a conductive material may have a more uniform crystalline structure throughout its thickness than a deposited semiconductor material (e.g., where the thickness is a dimension of the semiconductor material in a plane substantially orthogonal to the substrate, such as along the z-axis as illustrated in FIG. 2A). For example, a deposited semiconductor material may start with small grains on the surface upon which the semiconductor material is deposited and grow from the small grains, which may result in a gradient (e.g., from smaller to larger) of grain sizes along the thickness of the semiconductor material. In contrast, a semiconductor material converted from a conductive material may have a substantially uniform grain size along a thickness of the semiconductor material due to starting with a relatively uniform metal layer that is then converted (e.g., via exposure to a gas and elevated temperatures). Also as a result of conversion from a conductive material, there may be no grain boundaries in at least about the first 2 nanometers of the semiconductor material (e.g., from an interface with another material) in the z-direction. For example, if the thickness of a semiconductor material that was converted is the dimension of the semiconductor material between a first material below the semiconductor material and a second material over the semiconductor material, a grain boundary may be absent from the semiconductor material in at least a first 2 nanometers of the thickness from a first interface with the first material towards a second interface with the second material. In one such example, such semiconductor materials converted from a conductive material may utilize a two-dimensional (2D) electron gas to facilitate charge carrier transport.

One example of semiconductor materials that may be formed by converting a conductive material are oxide semiconductors. For example, indium oxide may be formed by first depositing a layer of indium and converting the indium to indium oxide (e.g., via exposure to oxygen at elevated temperatures). Another example of semiconductor materials that are converted from a conductive material are semiconductive transition metal dichalcogenides (TMDs). TMDs include semiconducting materials formed form a combination of a transition metal (e.g., molybdenum or tungsten) and a chalcogen (e.g., sulfur or selenium) in a monolayer having a hexagonal crystal structure. TMDs are atomically thin materials having the general formula MX2, where M is a transition metal such as molybdenum (Mo), tungsten (W), or zirconium (Zr), and X is a chalcogen atom (sulfur(S), selenium (Se), or tellurium (Te)). TMDs that include Mo, W, or Zr as the transition metal are semiconducting. For example, MoS₂ and WS₂ are examples of N-type semiconductor materials, and MoSe₂ is an example of a P-type semiconductor material. TMD materials are in the class of 2D materials, also referred to as single-layer materials, such as graphene. 2D materials are crystalline materials that may be formed from a single material layer, e.g., a single layer of atoms. In some examples, a 2D material may include multiple monolayers and still be referred to as a 2D material. A single layer of a TMD, also referred to as a monolayer TMD, is composed of three atomic planes: two planes of the chalcogen atoms and one plane of the transition metal atoms. The transition metal (M) atoms are sandwiched between the two layers of the chalcogen (X) atoms.

Thus, as mentioned above the regions 202, 204, and 206 include at least two different materials. In some examples, the regions 202, 204, 206 may include a TMD and another type of semiconductor material (such as an oxide semiconductor), different TMDs, different oxide semiconductors, or an oxide semiconductor and another type of semiconductor. In one such example, one of the first and second semiconductor materials of the respective regions 202, 204 is a TMD and another of the first and second semiconductor materials is a semiconductor including oxygen. In another example, one of the first and second semiconductor materials of the respective regions 202, 204 is a first TMD and another of the first and second semiconductor materials is a second TMD. In another example, one of the first and second semiconductor materials of the respective regions 202, 204 is a first semiconductor including oxygen and another of the first and second semiconductor materials is a second semiconductor including oxygen. One or more of the semiconductor materials of the regions 202, 204, and 206, may also be a 2D material.

FIG. 2B is a diagram of another example device fabricated with N-type and P-type semiconductor material stacking techniques, in accordance with various embodiments. In the example illustrated in FIG. 2B, the device 203B includes a fourth region 207 stacked over and in contact with the region 206. In one example, the device 203B is a vertical thyristor, with vertically stacked alternating N-type and P-type regions. In the example illustrated in FIG. 2B, the regions 202 and 206 may include the same semiconductor material, and the regions 204 and 207 may include the same semiconductor material. The regions 202 and 206 may have one charge-carrier type (e.g., either N-type or P-type), and the regions 204 and 207 may have the other charge-carrier type (e.g., if regions 202 and 207 include an N-type semiconductor material, then regions 204 and 206 include a P-type semiconductor material).

In addition to forming vertical devices with stacked alternating layers of N-type and P-type semiconductor material, the N-type and P-type semiconductor material stacking techniques may be used to stack multiple vertical devices over one another. For example, FIG. 3 is a block diagram of an IC structure 300 with multiple stacked devices. The IC structure 300 includes a device 303-1, an interconnect 340 over and coupled with the device 303-1 and another device 303-2 over and coupled with the interconnect 340. Each of the devices 303-1, 303-2 may include a transistor or other device with stacked alternating layers of N-type and P-type semiconductor material. The interconnect 340 may represent a conductive interconnect, such as a conductive line and/or via in a layer of an insulator material. For example, if the device 303-1 represents the transistor 203A of FIG. 2, the conductive interconnect 340 may be over and coupled with the third semiconductor region 206, and the device 303-2 may be a similar transistor. For example, if the device 303-1 includes the first region 202, second region 204, and third region 206, the device 303-2 may include a fourth semiconductor region over and coupled with the conductive interconnect 340, a fifth semiconductor region over and in contact with the fourth semiconductor region (where one of the fourth and fifth semiconductor regions includes N-type dopants, and another of the fourth and fifth semiconductor regions includes P-type dopants) and a sixth semiconductor region over and in contact with the fifth semiconductor region (where the sixth semiconductor region includes a same type dopant as the fourth semiconductor region). Further devices may be stacked and interconnected, as indicated by the device 303-N.

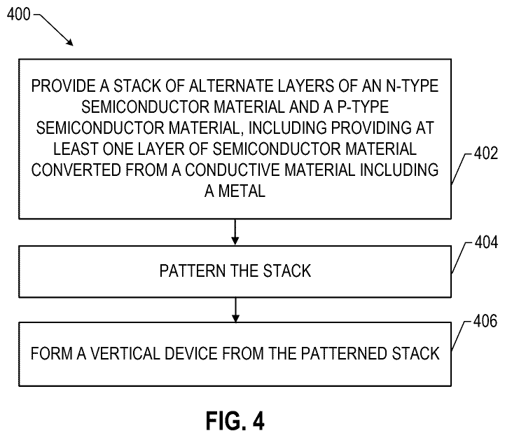

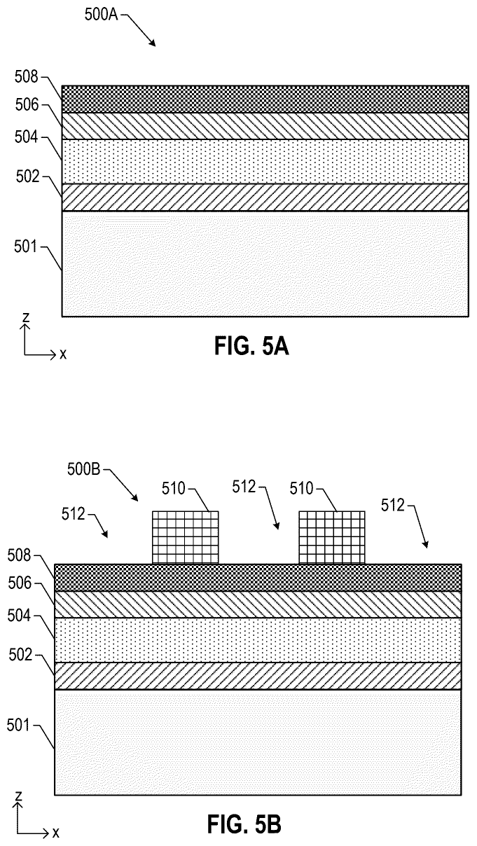

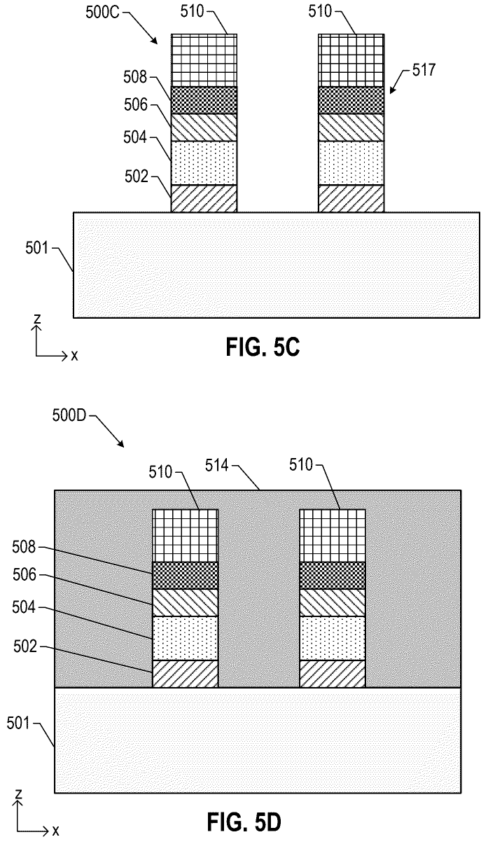

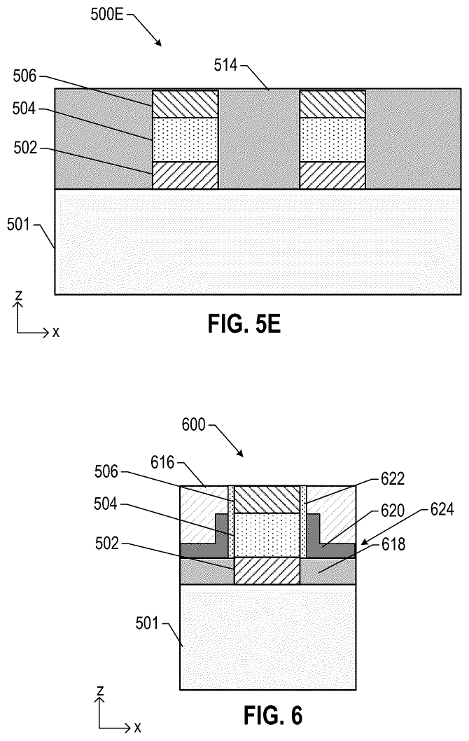

FIG. 4 is a flow diagram of an example method 400 for fabricating an IC structure using N-type and P-type semiconductor stacking techniques. FIGS. 5A-5E provide cross-sectional side views at various stages in the fabrication of an example IC structure according to the method of FIG. 4, in accordance with some embodiments. Although the operations of the method of FIG. 4 are illustrated once each and in a particular order, the operations may be performed in any suitable order and repeated as desired. For example, one or more operations may be performed in parallel to fabricate multiple IC structures using N-type and P-type semiconductor stacking techniques substantially simultaneously. In another example, the operations may be performed in a different order to reflect the structure of an IC device in which N-type and P-type semiconductor stacking techniques will be implemented.

In addition, the example fabricating methods of FIG. 4 may include other operations not specifically shown in FIG. 4, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 4 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 4, the method 400 begins with a process 402 of providing a stack of alternate layers of an N-type semiconductor and a P-type semiconductor, including providing at least one layer of semiconductor material converted from a conductive material including a metal. The IC structure 500A of FIG. 5A is an example resulting structure of the process 402. The IC structure 500A includes a substrate 501 and layers 502, 504, and 506 of semiconductor material. The substrate 501 may be an example of the substrate 102 of FIG. 1, may be a BEOL layer (e.g., an interconnect layer), or other layer of material or support structure over which the stack may be provided. In the example illustrated in FIG. 5A, the IC structure 500A also includes a barrier layer 508 over the stack of alternate layers of N-type semiconductor material and P-type semiconductor material. While FIG. 5A illustrates three layers of alternating N-type and P-type semiconductor material, in other embodiments, fewer or more than three layers may be used.

Providing a layer of semiconductor material may involve any suitable deposition technique, such as atomic layer deposition (ALD), chemical vapor deposition (CVD), physical vapor deposition (PVD), epitaxial deposition, conversion from a conductive material using a gas treatment, or any other technique may be used, as long as at least one of the layers 502, 504, and 506 is formed by converting a conductive material. In one example, providing a layer of semiconductor material by converting a layer of conductive material may involve first depositing a layer of conductive material (e.g., using an ALD process or other suitable deposition technique). A treatment, such as a gas treatment, may then be performed on the conductive material. In one example, a gas treatment involves exposing the conductive material to a gas (e.g., hydrogen sulfide, hydrogen selenide, oxygen, or other gas) at a temperature in a range of about 350 to 600 degrees C. In some examples, the metal to semiconductor conversion process may be a lower temperature process than, e.g., an epitaxial deposition process, and may enable providing semiconductor materials by conversion from conductive materials in BEOL layers.

The method 400 continues with the process 404 of patterning the stack. The IC structures 500B and 500C of FIGS. 5B and 5C are example resulting structures of the process 404. The IC structure 500B includes a mask 510 with openings 512. FIG. 5C illustrates the IC structure 500C after etching the layers 502, 504, and 506 through the openings 512 in the mask 510 using any suitable etch technique. A resulting portion 517 of the patterned stack includes a first semiconductor region (e.g., the semiconductor material 502) and a second semiconductor region (e.g., the semiconductor material 504) over and in contact with the first semiconductor region, where one of the first and second semiconductor regions includes N-type dopants, and another of the first and second semiconductor regions includes P-type dopants. The portion 517 also includes a third semiconductor region (e.g., the semiconductor material 506) over and in contact with the second semiconductor region, where the third semiconductor region includes a same type dopant as the first semiconductor region. An insulator material may then be provided in the openings 512. FIG. 5D illustrates an example IC structure 500D in which an insulator material 514 has been deposited around the patterned structures. The IC structure may then be polished to facilitate forming a vertical transistor from the patterned stack in the process 406, as shown in the IC structure 500E of FIG. 5E.

FIG. 6 illustrates an example of an IC structure 600 including a vertical transistor. Forming a vertical transistor from the portion 517 may involve, for example, recessing the insulator material 514 to expose the second semiconductor region (e.g., the semiconductor material 504, depositing an insulator material 618 around the first semiconductor region (e.g., around the semiconductor material 502), providing an insulator material (e.g., a gate insulator material) 622 around the second semiconductor region (e.g., around the semiconductor material 504), providing a conductive material (e.g., electrode material) 620 around the insulator material 622, and providing a second insulator material 616 around the conductive material 620.

Thus, FIG. 4 illustrates a method 400 for fabricating an IC structure using N-type and P-type semiconductor stacking techniques. Performing the method 400 may result in several features in the final IC structures that are characteristic of the use of the method 400. For example, one such feature is illustrated in an IC structure 600 shown in FIG. 6, which shows a stack of alternate layers of N-type doped semiconductor material and P-type doped semiconductor material including a first semiconductor material 502, a second semiconductor material 504 over the first semiconductor material 502, where the second semiconductor material 504 has a different material composition from the first semiconductor material 504, and a third semiconductor material 506 over the second semiconductor material 504, where the third semiconductor material 506 may have substantially a same material composition as the first semiconductor material. A first conductive contact structure or electrode (not shown in FIG. 6) may be below and coupled with the first semiconductor material 502, a second conductive contact structure or electrode 624 may be coplanar with and in contact with the second semiconductor material 504, and a third conductive contact structure (not shown in FIG. 6) may be over and coupled with the third semiconductor material 506.

IC devices/structures fabricated using N-type and P-type semiconductor stacking techniques as described herein (e.g., as described with reference to FIGS. 1-6) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

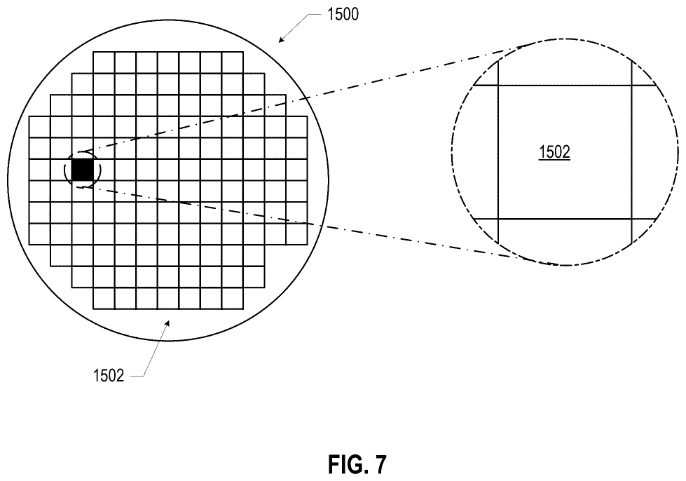

The IC devices/structures disclosed herein, e.g., the IC structures 100, 300, 500E, 600, or any variations thereof, may be included in any suitable electronic component. FIGS. 7-10 illustrate various examples of apparatuses that may include any of the IC devices disclosed herein.

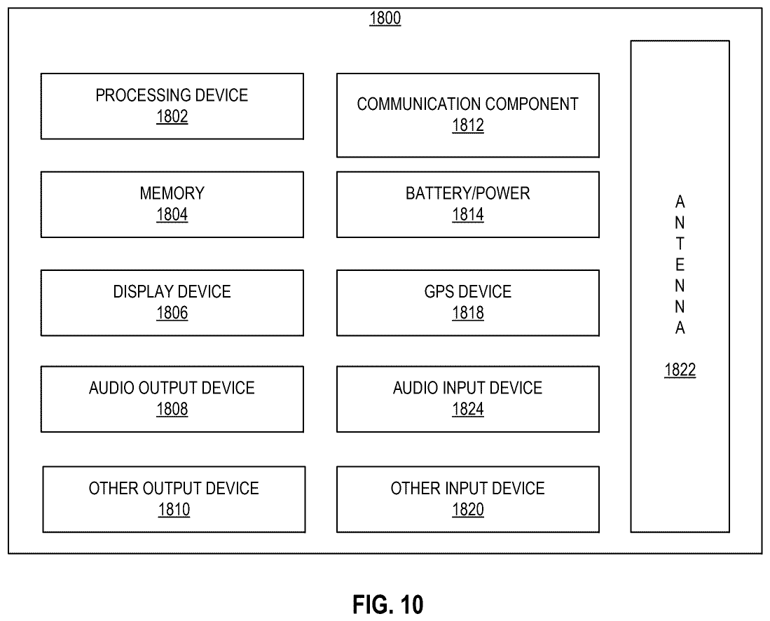

FIG. 7 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC structures 100, 300, 500E, 600, or any variations thereof described herein, or any combination of such IC structures), one or more transistors and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

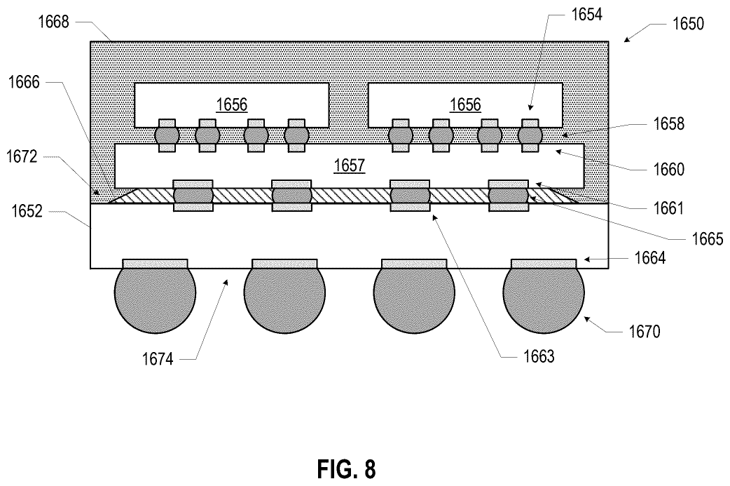

FIG. 8 is a side, cross-sectional view of an example IC package 1650 that may include one or more IC structures in accordance with any of the embodiments disclosed herein (e.g., any of the IC structures 100, 300, 500E, 600, or any variations thereof described herein, or any combination of such IC structures). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 8 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 8 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

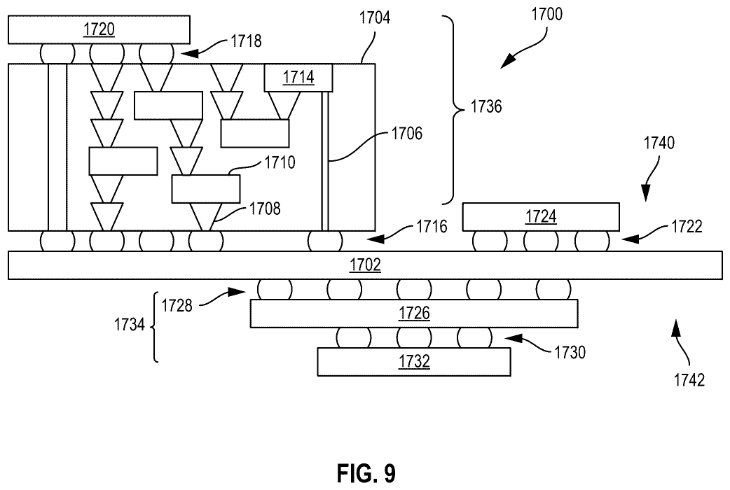

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 8 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 9.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 8 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 8, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 9 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 8 (e.g., may include one or more of the IC structures 100, 300, 500E, 600, or any variations thereof described herein, or any combination of such IC structures).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 7), an IC device (e.g., any of the IC structures 100, 300, 500E, 600, or any variations thereof described herein, or any combination of such IC structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 9, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 10 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 10, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC device, including a first semiconductor region over a substrate; a second semiconductor region over and in contact with the first semiconductor region, where one of the first and second semiconductor regions includes N-type dopants, and another of the first and second semiconductor regions includes P-type dopants; and a third semiconductor region over and in contact with the second semiconductor region, where the third semiconductor region includes a same charge-carrier-type dopant as the first semiconductor region, and where: at least one of the first, second, or third semiconductor regions includes a semiconductor material (e.g., semiconductor material converted from a conductive material) that has substantially uniform grain size along a thickness of the semiconductor material, where the thickness is a dimension of the semiconductor material in a plane substantially orthogonal to the substrate.

Example 2 provides the IC device of example 1, where: the thickness of the semiconductor material is the dimension of the semiconductor material between a first material below the semiconductor material and a second material over the semiconductor material; and a grain boundary is absent from the semiconductor material in at least a first 2 nanometers of the thickness from a first interface with the first material towards a second interface with the second material.

Example 3 provides the IC device of examples 1 or 2, where: the first semiconductor region includes a first semiconductor material; the second semiconductor region includes a second semiconductor material that is different from the first semiconductor; and the third semiconductor region includes a third semiconductor material that is substantially the same as the first semiconductor material.

Example 4 provides the IC device of any one of examples 1-3, where: one of the first and second semiconductor materials is a transition metal dichalcogenide and another of the first and second semiconductor materials is a semiconductor including oxygen.

Example 5 provides the IC device of any one of examples 1-3, where: one of the first and second semiconductor materials is a first TMD and another of the first and second semiconductor materials is a second TMD.

Example 6 provides the IC device of any one of examples 1-3, where: one of the first and second semiconductor materials is a first semiconductor including oxygen and another of the first and second semiconductor materials is a second semiconductor including oxygen.

Example 7 provides the IC device of any one of examples 1-6, where: one or more of the first semiconductor region, the second semiconductor region, and the third semiconductor region include a 2D material.

Example 8 provides the IC device of any one of examples 1-7, where: the first semiconductor region, the second semiconductor region, and the third semiconductor region are in front end of line layers.

Example 9 provides the IC device of any one of examples 1-7, where: the first semiconductor region, the second semiconductor region, and the third semiconductor region are in back end of line layers.

Example 10 provides the IC device of any one of examples 1-8, further including a conductive interconnect over and coupled with the third semiconductor region; a fourth semiconductor region over and coupled with the conductive interconnect; a fifth semiconductor region over and in contact with the fourth semiconductor region, where one of the fourth and fifth semiconductor regions includes N-type dopants, and another of the fourth and fifth semiconductor regions includes P-type dopants; and a sixth semiconductor region over and in contact with the fifth semiconductor region, where the sixth semiconductor region includes a same type dopant as the fourth semiconductor region.

Example 11 provides a transistor, including a stack of alternate layers of N-type doped semiconductor material and P-type doped semiconductor material including: a first semiconductor material, a second semiconductor material over the first semiconductor material, where the second semiconductor material has a different material composition from the first semiconductor material, and a third semiconductor material over the second semiconductor material, where the third semiconductor material has substantially a same material composition as the first semiconductor material; a first conductive contact structure below and coupled with the first semiconductor material; a second conductive contact structure coplanar with and in contact with the second semiconductor material; and a third conductive contact structure over and coupled with the third semiconductor material.

Example 12 provides the transistor of example 11, where: one of the first and second semiconductor materials is a transition metal dichalcogenide and another of the first and second semiconductor materials is a semiconductor including oxygen.

Example 13 provides the transistor of example 11, where: one of the first and second semiconductor materials is a first TMD and another of the first and second semiconductor materials is a second TMD.

Example 14 provides the transistor of example 11, where: one of the first and second semiconductor materials is a first semiconductor including oxygen and another of the first and second semiconductor materials is a second semiconductor including oxygen.

Example 15 provides the transistor of any one of examples 11-14, where: one or more of the first semiconductor material, the second semiconductor material, and the third semiconductor material is a 2D material.

Example 16 provides the transistor of any one of examples 11-15, where: the stack is in a front-end device region.

Example 17 provides the transistor of any one of examples 11-15, where: the stack is over an interconnect layer.

Example 18 provides the transistor of any one of examples 11-17, where the stack is a first stack, and where the transistor further includes a conductive interconnect over and coupled with the third electrode; and a second stack of alternate layers of N-type doped semiconductor material and P-type doped semiconductor material including: the first semiconductor material, the second semiconductor material over the first semiconductor material, and the third semiconductor material over the second semiconductor material.

Example 19 provides an IC structure according to any one of examples 1-18, where the IC structure includes or is a part of a central processing unit.

Example 20 provides an IC structure according to any one of examples 1-19, where the IC structure includes or is a part of a memory device.

Example 21 provides an IC structure according to any one of examples 1-20, where the IC structure includes or is a part of a logic circuit.

Example 22 provides an IC structure according to any one of examples 1-21, where the IC structure includes or is a part of input/output circuitry.

Example 23 provides an IC structure according to any one of examples 1-22, where the IC structure includes or is a part of a field programmable gate array transceiver.

Example 24 provides an IC structure according to any one of examples 1-23, where the IC structure includes or is a part of a field programmable gate array logic.

Example 25 provides an IC structure according to any one of examples 1-24, where the IC structure includes or is a part of a power delivery circuitry.

Example 26 provides an IC package that includes an IC die including an IC structure according to any one of examples 1-25; and a further IC component, coupled to the IC die.

Example 27 provides an IC package according to example 26 where the further IC component includes a package substrate.

Example 28 provides an IC package according to example 26, where the further IC component includes an interposer.

Example 29 provides an IC package according to example 26, where the further IC component includes a further IC die.

Example 30 provides a computing device that includes a carrier substrate and an IC structure coupled to the carrier substrate, where the IC structure is an IC structure according to any one of examples 1-25, or the IC structure is included in the IC package according to any one of examples 26-29.

Example 31 provides a computing device according to example 30, where the computing device is a wearable or handheld computing device.

Example 32 provides a computing device according to examples 30 or 31, where the computing device further includes one or more communication chips.

Example 33 provides a computing device according to any one of examples 30-32, where the computing device further includes an antenna.

Example 34 provides a computing device according to any one of examples 30-33, where the carrier substrate is a motherboard.

Example 35 provides a method of fabricating an IC structure, the method including providing a stack of alternate layers of N-type doped semiconductor material and P-type doped semiconductor material, where providing at least one layer of the stack includes depositing a conductive material including a metal, and converting the conductive material to a semiconductor material; patterning the stack, where: a portion of the patterned stack includes a first semiconductor region and a second semiconductor region over and in contact with the first semiconductor region, and one of the first and second semiconductor regions includes N-type dopants, and another of the first and second semiconductor regions includes P-type dopants; and forming a (vertical) device from the portion of the patterned stack.

Example 36 provides the method of example 35, where: the portion further includes a third semiconductor region over and in contact with the second semiconductor region, and the third semiconductor region includes a same type dopant as the first semiconductor region.

Example 37 provides the method of example 36, where: forming the device includes providing a first insulator material around the portion, recessing the first insulator material to expose the second semiconductor region but not the first semiconductor region, providing a gate insulator material around the second semiconductor region, providing a conductive material around the gate insulator material, and providing a second insulator material around the conductive material.

Example 38 provides the method of example 36, where: the portion further includes a fourth semiconductor region over and in contact with the third semiconductor region, and the fourth semiconductor region includes a same type dopant as the second semiconductor region.

Example 39 provides the method of any one of examples 35-38, where: converting the conductive material to the semiconductor material includes exposing the conductive material to a gas (e.g., at a temperature of 350-700 degrees C.).

Example 40 provides the method of any one of examples 35-39, where: providing at least two layers of the stack includes depositing a conductive material and converting the conductive material to a semiconductor material.

Example 41 provides the method of any one of examples 35-40, where the stack is a first stack, the device is a first device, and where the method further includes providing a conductive interconnect over and coupled with the first device; providing a second stack of alternate layers of N-type doped semiconductor material and P-type doped semiconductor material, where providing at least one layer of the stack includes depositing a conductive material, and converting the conductive material to a semiconductor material; patterning the second stack; and forming a device from a portion of the second patterned stack.

Example 42 provides a method according to any one of examples 35-41, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first semiconductor region over a substrate;
a second semiconductor region over and in contact with the first semiconductor region, wherein one of the first and second semiconductor regions includes N-type dopants, and another of the first and second semiconductor regions includes P-type dopants; and
a third semiconductor region over and in contact with the second semiconductor region, wherein the third semiconductor region includes a same charge-carrier-type dopants as the first semiconductor region, and wherein:
at least one of the first, second, or third semiconductor regions includes a semiconductor material that has substantially uniform grain size along a thickness of the semiconductor material, wherein the thickness is a dimension of the semiconductor material in a plane substantially orthogonal to the substrate.

2. The IC device of claim 1, wherein:
the thickness of the semiconductor material is the dimension of the semiconductor material between a first material below the semiconductor material and a second material over the semiconductor material, and
a grain boundary is absent from the semiconductor material in at least a first 2 nanometers of the thickness from a first interface with the first material towards a second interface with the second material.

3. The IC device of claim 1, wherein:
the first semiconductor region includes a first semiconductor material,
the second semiconductor region includes a second semiconductor material that is different from the first semiconductor, and
the third semiconductor region includes a third semiconductor material that is substantially the same as the first semiconductor material.

4. The IC device of claim 1, wherein:
one of the first and second semiconductor materials is a transition metal dichalcogenide and another of the first and second semiconductor materials is a semiconductor including oxygen.

5. The IC device of claim 1, wherein:
one of the first and second semiconductor materials is a first transition metal dichalcogenide (TMD) and another of the first and second semiconductor materials is a second TMD.

6. The IC device of claim 1, wherein:
one of the first and second semiconductor materials is a first semiconductor including oxygen and another of the first and second semiconductor materials is a second semiconductor including oxygen.

7. The IC device of claim 1, wherein:
one or more of the first semiconductor region, the second semiconductor region, and the third semiconductor region include a two-dimensional (2D) material.

8. The IC device of claim 1, wherein:
the first semiconductor region, the second semiconductor region, and the third semiconductor region are in front end of line layers.

9. The IC device of claim 1, wherein:
the first semiconductor region, the second semiconductor region, and the third semiconductor region are in back end of line layers.

10. The IC device of claim 1, further comprising:
a conductive interconnect over and coupled with the third semiconductor region;
a fourth semiconductor region over and coupled with the conductive interconnect;
a fifth semiconductor region over and in contact with the fourth semiconductor region, wherein one of the fourth and fifth semiconductor regions includes N-type dopants, and another of the fourth and fifth semiconductor regions includes P-type dopants; and
a sixth semiconductor region over and in contact with the fifth semiconductor region, wherein the sixth semiconductor region includes a same type dopant as the fourth semiconductor region.

11. A transistor, comprising:
a stack of alternate layers of an N-type doped semiconductor material and a P-type doped semiconductor material, the stack including:
a first semiconductor material,
a second semiconductor material over the first semiconductor material, wherein the second semiconductor material has a different material composition from the first semiconductor material, and
a third semiconductor material over the second semiconductor material, wherein the third semiconductor material has substantially a same material composition as the first semiconductor material;
a first conductive contact structure below and coupled with the first semiconductor material;
a second conductive contact structure coplanar with and in contact with the second semiconductor material; and
a third conductive contact structure over and coupled with the third semiconductor material.

12. The transistor of claim 11, wherein:
one of the first and second semiconductor materials is a transition metal dichalcogenide and another of the first and second semiconductor materials is a semiconductor including oxygen.

13. The transistor of claim 11, wherein:
one of the first and second semiconductor materials is a first transition metal dichalcogenide (TMD) and another of the first and second semiconductor materials is a second TMD.

14. The transistor of claim 11, wherein:
one of the first and second semiconductor materials is a first semiconductor including oxygen and another of the first and second semiconductor materials is a second semiconductor including oxygen.

15. The transistor of claim 11, wherein:
one or more of the first semiconductor material, the second semiconductor material, and the third semiconductor material is a two-dimensional (2D) material.

16. The transistor of claim 11, wherein:
the stack is in a front-end device region.

17. The transistor of claim 11, wherein:
the stack is over an interconnect layer.

18. The transistor of claim 11, wherein the stack is a first stack, and wherein the transistor further comprises:
a conductive interconnect over and coupled with the third conductive contact; and
a second stack of alternate layers of N-type doped semiconductor material and P-type doped semiconductor material including:
the first semiconductor material,
the second semiconductor material over the first semiconductor material, and
the third semiconductor material over the second semiconductor material.

19. A method of fabricating an integrated circuit (IC) structure, the method comprising:
providing a stack of alternate layers of an N-type doped semiconductor material and a P-type doped semiconductor material, wherein providing at least one layer of the stack includes:
depositing a conductive material including a metal, and
converting the conductive material to a semiconductor material;
patterning the stack, wherein:
a portion of the patterned stack includes a first semiconductor region and a second semiconductor region over and in contact with the first semiconductor region, and
one of the first and second semiconductor regions includes N-type dopants, and
another of the first and second semiconductor regions includes P-type dopants; and
forming a device from the portion of the patterned stack.

20. The method of claim 19, wherein:
the portion further includes a third semiconductor region over and in contact with the second semiconductor region, and the third semiconductor region includes a same type dopant as the first semiconductor region.
